(19) United States
(12) Patent Application Publication
(10) Pub. No.: US 2025/0287727 A1
(43) Pub. Date: Sep. 11, 2025

(54) LIGHT EMITTING DIODE CHIP AND MANUFACTURING METHOD THEREOF

(71) Applicant: INGENTEC CORPORATION, Miaoli County (TW)

(72) Inventors: Hsiao-Lu CHEN, Miaoli County (TW); Ai-Sen LIU, Miaoli County (TW); Hsiang-An FENG, Miaoli County (TW)

(21) Appl. No.: 18/914,260

(22) Filed: Oct. 14, 2024

(30) Foreign Application Priority Data
Mar. 11, 2024 (TW) 113108793

(51) Int. Cl. H01L 33/00; H01L 33/20

(52) U.S. Cl. CPC H10H 20/01; H10H 20/819

(57) ABSTRACT

A manufacturing method of a light emitting diode chip includes disposing a plurality of light emitting diode elements on a surface of a substrate, covering the plurality of light emitting diode elements and the surface of the substrate with a photoresist layer, patterning the photoresist layer with a photomask to form a to-be-etched structure, spray-etching the to-be-etched structure and then removing the photoresist layer to form an etched structure, transferring the etched structure onto an elastic film, and stretching the elastic film to break a plurality of connection portions of the etched structure so as to form a plurality of light emitting diode chips.

### RELATED APPLICATIONS

This application claims priority to Taiwan Application Serial Number 113108793, filed Mar. 11, 2024, which is herein incorporated by reference.

### BACKGROUND

### Technical Field

The present disclosure relates to a light emitting diode chip and a manufacturing method thereof. More particularly, the present disclosure relates to a light emitting diode chip segmented via structural expansion and a manufacturing method thereof.

### Description of Related Art

A conventional manufacturing method of a light emitting diode chip involves performing epitaxy on a substrate so as to manufacture a preliminary diode structure, and then dicing the substrate so as to separate the substrate into multiple light emitting diode chips. There are three main dicing processes, including laser dicing, knife dicing, and plasma dicing. In short, laser dicing and plasma dicing are respectively performed with a high-power laser and a thermal plasma to melt the substrate so as to cause the substrate to break with notches, while knife dicing involves dicing the substrate with a sharp knife.

A common problem of laser dicing, knife dicing, and plasma dicing is that the dicing speed is slow, and a high temperature is easily generated in the dicing process so as to cause thermal damage to the light emitting diode chips, thus affecting the service life of the light emitting diode chips. Moreover, laser dicing, knife dicing, and plasma dicing easily cause dimensional errors during dicing thin metal substrates or composite metal substrates, which further reduces the yield of light emitting diode chips.

For all these reasons, it is necessary to improve the shortcomings associated with performing separation to form multiple light emitting diode chips.

### SUMMARY

According to one aspect of the present disclosure, a manufacturing method of a light emitting diode chip includes the steps as outlined below. A plurality of light emitting diode elements are disposed on a surface of a substrate, wherein the plurality of light emitting diode elements are spaced apart from each other. The plurality of light emitting diode elements and the surface of the substrate are covered with a photoresist layer. The photoresist layer is patterned with a photomask to form a to-be-etched structure. The to-be-etched structure is spray-etched and then the photoresist layer is removed to form an etched structure, wherein the etched structure includes a plurality of chip portions and a plurality of connection portions, each of the plurality of connection portions is between adjacent two of the plurality of chip portions and connects to the adjacent two of the plurality of chip portions, and the plurality of light emitting diode elements are on the plurality of chip portions, respectively. The etched structure is transferred onto an elastic film. The elastic film is stretched to break the plurality of connection portions so as to form a plurality of light emitting diode chips.

According to another aspect of the present disclosure, a light emitting diode chip is manufactured by the manufacturing method of the light emitting diode chip of the aforementioned aspect. The substrate of the light emitting diode chip includes a body and at least one protruding portion, and the at least one protruding portion connects to the body and extends outwards from the body.

### BRIEF DESCRIPTION OF THE DRAWINGS

The present disclosure can be more fully understood by reading the following detailed description of the embodiments, with reference made to the accompanying drawings as follows:

FIG. 1 is a flow chart of a manufacturing method of a light emitting diode chip according to one embodiment of the present disclosure.

FIG. 2, FIG. 3, FIG. 4, FIG. 5A, FIG. 5B, FIG. 6, FIG. 7A, and FIG. 7B are respectively structural schematic views of each step in the manufacturing method of the light emitting diode chip.

FIG. 8 is a structural schematic view of a light emitting diode chip.

### DETAILED DESCRIPTION

The present disclosure will be further exemplified by the following specific embodiments. However, the embodiments can be applied to various inventive concepts and can be embodied in various specific ways. The specific embodiments are only for the purposes of description, and are not limited to these practical details thereof. In addition, some conventional structures and elements are illustrated in the drawings in a simple and schematic way, and repeated elements can be presented by the same or similar reference numerals.

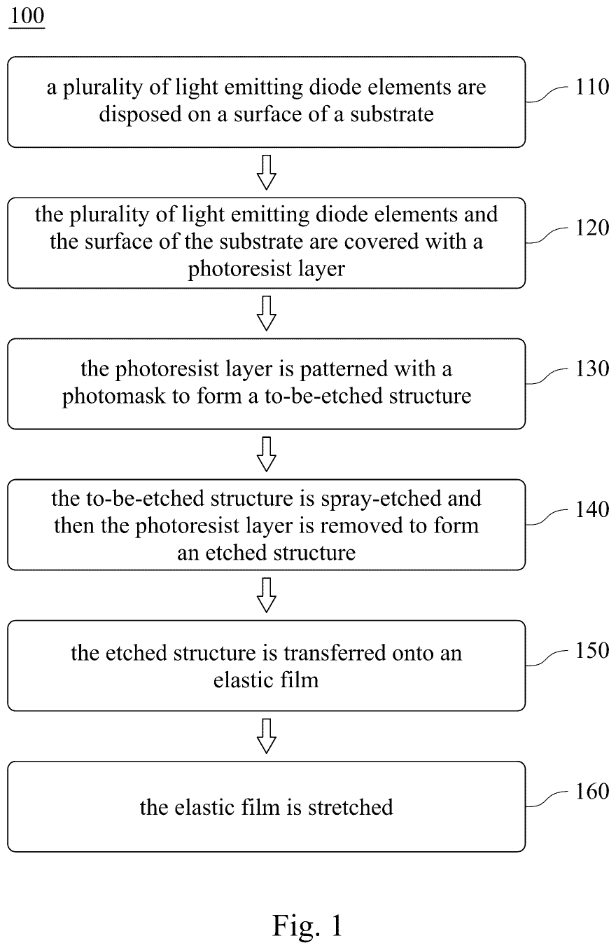

FIG. 1 is a flow chart of a manufacturing method of a light emitting diode chip 100 according to one embodiment of the present disclosure. The manufacturing method of the light emitting diode chip 100 includes step 110, step 120, step 130, step 140, step 150, and step 160.

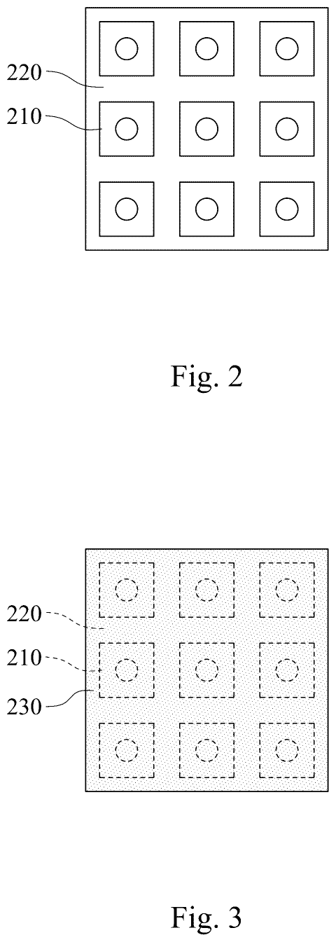

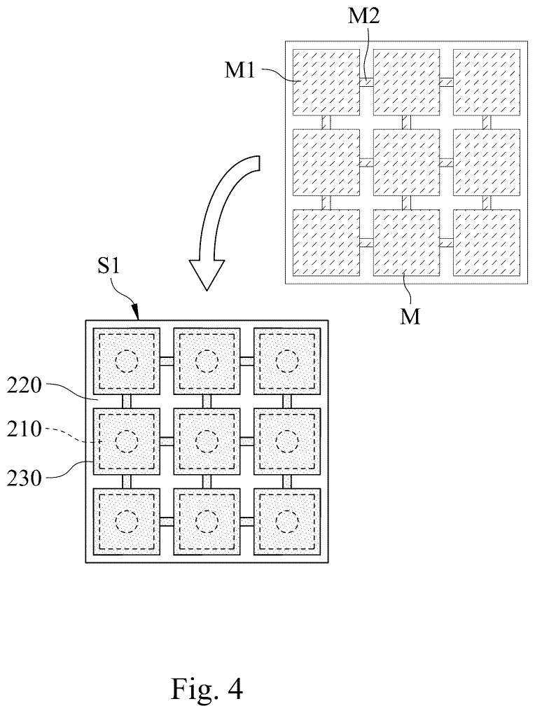

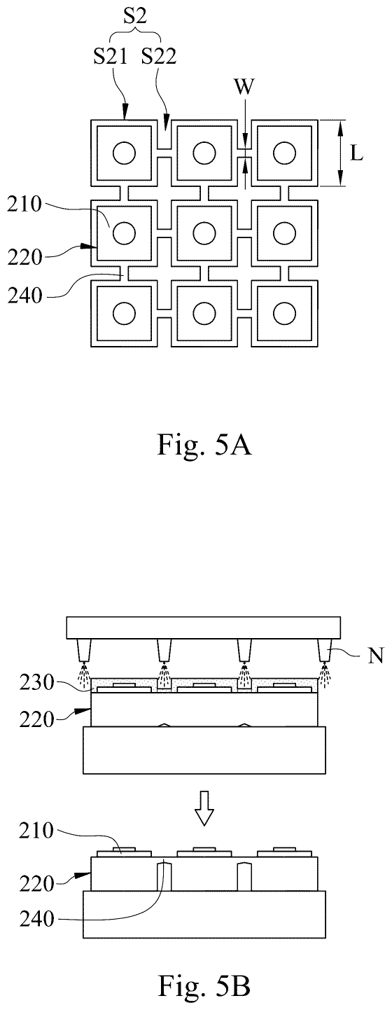

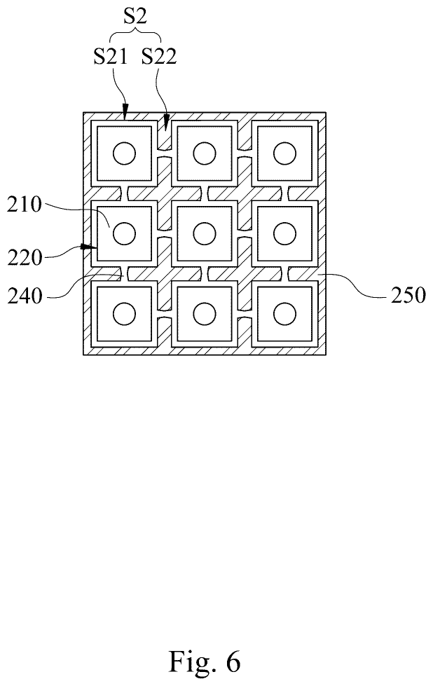

FIG. 2 is a structural schematic view of step 110 in the manufacturing method of the light emitting diode chip 100. In step 110, a plurality of light emitting diode elements 210 are disposed on a surface of a substrate 220, wherein the plurality of light emitting diode elements 210 are spaced apart from each other in order to retain an appropriate space, which is favorable for a subsequent separation. The substrate 220 can be a composite metal substrate. The composite metal substrate can include at least two structural layers, and a material of each of the at least two structural layers can include at least one of copper, nickel and iron. For example, the composite metal substrate can include a multi-layer structure, and a material of each of the layers can be adjusted according to physicochemical properties or circuit requirements, but the present disclosure is not limited thereto.

FIG. 3 is a structural schematic view of step 120 in the manufacturing method of the light emitting diode chip 100. In step 120, the plurality of light emitting diode elements 210 and the surface of the substrate 220 are covered with a photoresist layer 230. The photoresist layer 230 can be made of a positive-photoresist material or a negative-photoresist material, in which the positive-photoresist material is taken as an example to illustrate the present disclosure, but the present disclosure is not limited thereto.

FIG. 4 is a structural schematic view of step 130 in the manufacturing method of the light emitting diode chip 100. In step 130, the photoresist layer 230 is patterned with a photomask M to form a to-be-etched structure S1. In detail, the photomask M can include a plurality of first light-shielding portions M1 and a plurality of second light-shielding portions M2, in which the plurality of first light-shielding portions M1 can respectively correspond to the plurality of light emitting diode elements 210 during patterning. An area of each of the plurality of first light-shielding portions M1 can be slightly larger than an area of each of the plurality of light emitting diode elements 210, and each of the plurality of second light-shielding portions M2 can be between adjacent two of the plurality of first light-shielding portions M1 and connect to the adjacent two of the plurality of first light-shielding portions M1.

FIG. 5A is a structural schematic view of step 140 in the manufacturing method of the light emitting diode chip 100, and FIG. 5B is another structural schematic view of step 140 in the manufacturing method of the light emitting diode chip 100. In step 140, the to-be-etched structure S1 is spray-etched, and then the photoresist layer 230 is removed to form an etched structure S2. The to-be-etched structure S1 can be sprayed by a micro-nozzle N with an etching solution during spray-etching. Therefore, the substrate 220 that is not covered by the photomask M can be removed and a portion of the substrate 220 that is covered by the plurality of second light-shielding portions M2 can be removed so as to form a mesh-arrangement structure as shown in FIG. 5A.

In detail, the substrate 220 can be the composite metal substrate and can include the at least two structural layers. Preferably, the substrate 220 can include two to five structural layers so as to obtain an appropriate etching selectivity ratio during spray-etching. That is, the etching solution can etch different structural layers with different etching speeds and leave remaining the at least two structural layers close to the photomask M. Moreover, the spray-etching can further reduce a lateral etching of the substrate 220, which is favorable for forming the mesh-arrangement structure as shown in FIG. 5A.

The etched structure S2 includes a plurality of chip portions S21 and a plurality of connection portions S22. Each of the plurality of connection portions S22 is between adjacent two of the plurality of chip portions S21 and connects to the adjacent two of the plurality of chip portions S21, and the plurality of light emitting diode elements 210 are on the plurality of chip portions S21, respectively. In FIG. 5B, when the portion of the substrate 220 covered by the plurality of second light-shielding portions M2 is removed, a plurality of tethers 240 which are thin can be formed and the plurality of tethers 240 belong to the plurality of connection portions S22.

Furthermore, each of the plurality of connection portions S22 has a width W, each of the plurality of chip portions S21 has an edge-length L, and a ratio of the width W to the edge-length L can be 0.1 to 0.2. Therefore, a connection strength between the plurality of chip portions S21 can be increased and an efficiency in the subsequent separation of the plurality of chip portions S21 can be improved at the same time. The etched structure S2 can only include the plurality of chip portions S21 and the plurality of connection portions S22 so that the plurality of chip portions S21 can be separated successfully in the subsequent steps, and the present disclosure is not limited to the sizes of the plurality of chip portions S21 and the plurality of connection portions S22.

FIG. 6 is a structural schematic view of step 150 in the manufacturing method of the light emitting diode chip 100. In step 150, the etched structure S2 is transferred onto an elastic film 250, which is favorable for the subsequent separation of the plurality of chip portions S21.

FIG. 7A is a structural schematic view of step 160 in the manufacturing method of the light emitting diode chip 100, and FIG. 7B is another structural schematic view of step 160 in the manufacturing method of the light emitting diode chip 100. In step 160, the elastic film 250 is stretched to break the plurality of connection portions S22 so as to form a plurality of light emitting diode chips (not indicated with a reference numeral). When the plurality of connection portions S22 are broken, a protruding portion 260 can be formed at every edge of two of the plurality of chip portions S21 connected by one of the plurality of connection portions S22. Moreover, each of the plurality of connection portions S22 includes an extending direction. Taking a first extending direction D1 and a second extending direction D2 as an example, the elastic film 250 can be stretched parallel to the first extending direction D1 and the second extending direction D2. A center of each of the plurality of connection portions S22 can be thinner than two ends of each of the plurality of connection portions S22 connecting to the plurality of chip portions S21 so as to control breaking points of the plurality of connection portions S22 to reduce a possibility of damage to the plurality of chip portions S21 due to the break of the plurality of connection portions S22.

It should be noted that, although in FIG. 2 to FIG. 7B, a preparation of nine light emitting diode chips is taken as an example, during actual production, a number of the plurality of light emitting diode elements 210 and an area of the substrate 220 can be increased, and a shape of the photomask M can be adjusted accordingly so as to manufacture a large number of light emitting diode chips. The present disclosure is not limited to the number or the structure shown in FIG. 2 to FIG. 7B.

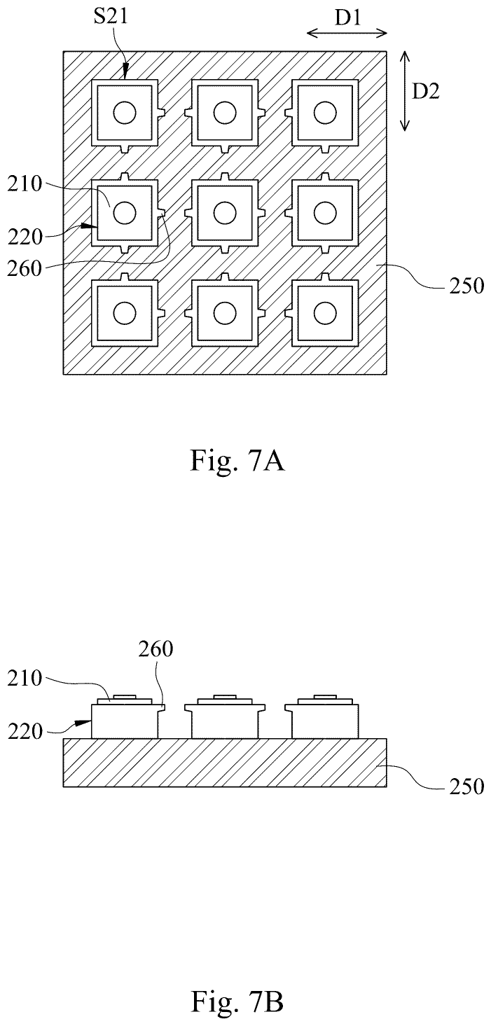

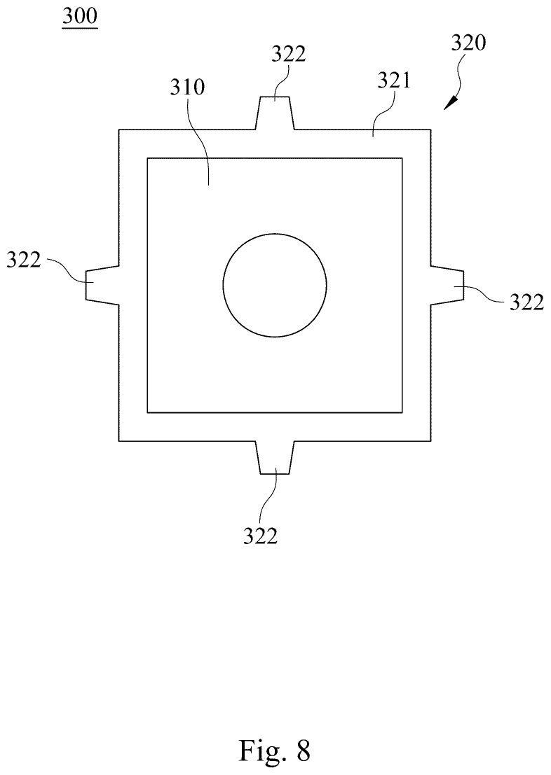

FIG. 8 is a structural schematic view of a light emitting diode chip 300. Another embodiment of the present disclosure provides the light emitting diode chip 300 which is manufactured by the aforementioned manufacturing method of the light emitting diode chip 100. A substrate 320 of the light emitting diode chip 300 includes a body 321 and at least one protruding portion 322, the at least one protruding portion 322 connects to the body 321 and extends outwards from the body 321, and the light emitting diode element 310 of the light emitting diode chip 300 is on the body 321.

In detail, when the aforementioned plurality of chip portions S21 are separated from each other, each of the plurality of connection portions S22 between the adjacent two of the plurality of chip portions S21 can be broken and leave the at least one protruding portion 322, and a number of the at least one protruding portion 322 can be four. The body 321 can be in a quadrilateral shape, and the four protruding portions 322 can connect to four edges of the body 321, respectively. In contrast, referring to FIG. 7A, the plurality of chip portions S21 at corners of the etched structure S2 only connect to two of the plurality of connection portions S22, such that in this case, the number of the at least one protruding portion 322 can be two, and the two protruding portions 322 can connect to adjacent two edges of the body 321, respectively. In further contrast, the plurality of chip portions S21 at edges of the etched structure S2 only connect to three of the plurality of connection portions S22, such that in this case, the number of the at least one protruding portion 322 can be three, and the three protruding portions 322 can connect to adjacent three edges of the body 321, respectively.

Furthermore, the center of each of the plurality of connection portions S22 can be thinner than the two ends of each of the plurality of connection portions S22 connecting to the plurality of chip portions S21, the at least one protruding portion 322 formed by breaking the plurality of connection portions S22 can be in a trapezoid shape, and a base edge of the at least one protruding portion 322 longer than another base edge of the at least one protruding portion 322 can connect to the body 321.

In conclusion, the manufacturing method of the light emitting diode chip of the present disclosure adjusts the etched structure so that the etched structure includes the plurality of chip portions and the plurality of connection portions, and the plurality of chip portions can be separated via stretching so as to significantly reduce structural damage, thermal damage and dimensional errors caused by the conventional dicing processes, and so as to improve an efficiency of manufacturing the light emitting diode chips.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a light emitting diode chip, comprising:
disposing a plurality of light emitting diode elements on a surface of a substrate, wherein the plurality of light emitting diode elements are spaced apart from each other;
covering the plurality of light emitting diode elements and the surface of the substrate with a photoresist layer;
patterning the photoresist layer with a photomask to form a to-be-etched structure;
spray-etching the to-be-etched structure and then removing the photoresist layer to form an etched structure, wherein the etched structure comprises a plurality of chip portions and a plurality of connection portions, each of the plurality of connection portions is between adjacent two of the plurality of chip portions and connects to the adjacent two of the plurality of chip portions, and the plurality of light emitting diode elements are on the plurality of chip portions, respectively;
transferring the etched structure onto an elastic film; and
stretching the elastic film to break the plurality of connection portions so as to form a plurality of light emitting diode chips.

2. The manufacturing method of the light emitting diode chip of claim 1, wherein the substrate is a composite metal substrate, and the composite metal substrate comprises at least two structural layers.

3. The manufacturing method of the light emitting diode chip of claim 2, wherein a material of each of the at least two structural layers comprises at least one of copper, nickel and iron.

4. The manufacturing method of the light emitting diode chip of claim 1, wherein the to-be-etched structure is sprayed by a micro-nozzle with an etching solution during spray-etching.

5. The manufacturing method of the light emitting diode chip of claim 1, wherein each of the plurality of connection portions has a width, each of the plurality of chip portions has an edge-length, and a ratio of the width to the edge-length is 0.1 to 0.2.

6. A light emitting diode chip, manufactured by the manufacturing method of the light emitting diode chip of claim 1;
wherein the substrate of the light emitting diode chip comprises a body and at least one protruding portion, and the at least one protruding portion connects to the body and extends outwards from the body.

7. The light emitting diode chip of claim 6, wherein a number of the at least one protruding portion is two, the body is in a quadrilateral shape, and the two protruding portions connect to adjacent two edges of the body, respectively.

8. The light emitting diode chip of claim 6, wherein a number of the at least one protruding portion is three, the body is in a quadrilateral shape, and the three protruding portions connect to adjacent three edges of the body, respectively.

9. The light emitting diode chip of claim 6, wherein a number of the at least one protruding portion is four, the body is in a quadrilateral shape, and the four protruding portions connect to four edges of the body, respectively.

10. The light emitting diode chip of claim 6, wherein the at least one protruding portion is in a trapezoid shape, and a base edge of the at least one protruding portion longer than another base edge of the at least one protruding portion connects to the body.
